(19) United States
(12) Patent Application Publication
(10) Pub. No.: US 2026/0188351 A1
(43) Pub. Date: Jul. 2, 2026

(54) HARD DISK ADAPTER APPARATUS, HARD DISK STORAGE SYSTEM, SERVER, AND COMPUTER DEVICE

(71) Applicant: Suzhou MetaBrain Intelligent Technology Co., Ltd., Suzhou (CN)

(72) Inventors: Hui TIAN, Suzhou (CN); Yu ZOU, Suzhou (CN); Yunwu PENG, Suzhou (CN)

(73) Assignee: Suzhou MetaBrain Intelligent Technology Co., Ltd., Suzhou, JS (CN)

(21) Appl. No.: 18/859,020

(22) PCT Filed: Dec. 19, 2023
(86) PCT No.: PCT/CN2023/139985

§ 371 Date: Oct. 22, 2024

(30) Foreign Application Priority Data
Dec. 23, 2022 (CN) 202211660375.1

(51) Int. Cl. G11B 33/12; H05K 7/14

(52) U.S. Cl. CPC G11B 33/122; H05K 7/1487; H05K 7/1489; H05K 7/1492

(57) ABSTRACT

A hard disk adapter apparatus comprises an adapter board. One end of the adapter board is provided with an adapter portion connected to a hard disk, and the other side of the adapter board is provided with a first connecting portion connected to a hard disk connector. The first connecting portion is centralized in a height direction of the adapter board. In the process of using the hard disk adapter apparatus provided by the present application, the hard disk and the hard disk connector can be connected by the hard disk adapter apparatus. The first connecting portion of the adapter board is centralized in the height direction of the adapter board, thereby facilitating the hard disk connector to be centralized in a height direction of a mid-plane.

### CROSS-REFERENCE TO RELATED APPLICATION

This application claims priority to Chinese Patent Application No. 202211660375.1, filed on Dec. 23, 2022 in China National Intellectual Property Administration and entitled “Hard Disk Adapter Apparatus, Hard Disk Storage System, Server, and Computer Device”, which is hereby incorporated by reference in its entirety.

### FIELD

The present application relates to the technical field of hard disk storage, in particular, to a hard disk adapter apparatus. Furthermore, the present application also relates to a hard disk storage system comprising the hard disk adapter apparatus, a server comprising the hard disk storage system, and a computer device comprising the server.

### BACKGROUND

In the related art, a dual-controller storage system with a height of 2U generally adopts the form of front disks and rear controllers. A front window is a 2.5-inch hard disk having a thickness of usually 15 mm. At most 25 hard disks can be placed in a front window of a 2U chassis. A rear window of the storage system is usually required with two controllers, which are stacked up and down, each occupying a height of 1U. The middle of the storage system is provided with a mid-plane. One side of the mid-plane is welded with hard disk connectors connected to the hard disks, and a gap between two adjacent hard disk connectors is about 11 mm. The other side of the mid-plane is welded with controller connectors connected to the controllers. Vent holes may be provided between two hard disk connectors on the mid-plane to ensure that the ventilation and heat dissipation effects of the two controllers stacked up and down are basically the same.

A new generation of E3.S hard disk is a latest hard disk form introduced in the storage industry. The appearance of the hard disk is different from that of a traditional 2.5-inch hard disk, and the thickness is only 7.5 mm. Therefore, the number of E3.S hard disks that may be placed in the front window of the 2U chassis is much more than that of ordinary hard disks. The gap between two adjacent hard disk connectors will be reduced, thereby resulting in insufficient space for signal interconnection routing of the mid-plane. In addition, a golden finger of the E3. S hard disk is not centralized. If the controllers are stacked up and down, the heat dissipation effects of the two controllers will be inconsistent, which will affect the performance of the overall machine.

### SUMMARY

In view of this, an objective of the present application is to provide a hard disk adapter apparatus. A hard disk and a hard disk connector can be connected by the hard disk adapter apparatus, whereby the hard disk connector can be arranged in the middle of a height direction of a mid-plane, and sufficient space can be reserved for heat dissipation of a controller, thereby facilitating uniform heat dissipation of the controller.

Another object of the present application is to provide a hard disk storage system comprising the hard disk adapter apparatus, a server comprising the hard disk storage system, and a computer device comprising the server.

In order to achieve the above objectives, the present application provides the following technical solutions.

According to a first aspect of the present application, a hard disk adapter apparatus is provided, comprising an adapter board. One end of the adapter board is provided with an adapter portion connected to a hard disk, and the other side of the adapter board is provided with a first connecting portion connected to a hard disk connector. The first connecting portion is centralized in a height direction of the adapter board.

In one implementation, the first connecting portion comprises a plurality of connecting structures arranged along the height direction of the adapter board. The connecting structures are connected to the hard disk connectors. The number of the connecting structures in the individual adapter boards is the same as the number of arrangement rows of the hard disk connectors.

In one implementation, the plurality of hard disk connectors are arranged in a top row and a bottom row, and the first connecting portion comprises a first connecting structure and a second connecting structure spaced apart in the height direction of the adapter board. The first connecting structure is connected to the hard disk connector in the top row, and the second connecting structure is connected to the hard disk connector in the bottom row.

In one implementation, the adapter board is provided with a control member connecting the adapter portion and the first connecting portion. The control member is configured to connect the adapter portion to one of the first connecting structure and the second connecting structure, which is connected to the hard disk connector.

In one implementation, the control member is a switching chip embedded in the adapter board.

In one implementation, the first connecting structure is provided with a first sensing member for detecting whether the first connecting structure is connected to the hard disk connector, and the second connecting structure is provided with a second sensing member for detecting whether the second connecting structure is connected to the hard disk connector. The first sensing member and the second sensing member are both connected to the switching chip.

The switching chip controls the adapter portion to be connected to the first connecting structure in case of receiving a signal that is sent by the first sensing member and indicates that the first connecting structure is connected to the hard disk connector. The switching chip controls the adapter portion to be connected to the second connecting structure in case of receiving a signal that is sent by the second sensing member and indicates that the second connecting structure is connected to the hard disk connector.

In one implementation, the adapter portion, the first connecting structure, and the second connecting structure are all golden fingers.

According to a second aspect of the present application, a hard disk storage system is provided, comprising:
a mid-plane, where one side of the mid-plane is provided with a plurality of hard disk connectors, the plurality of hard disk connectors are arranged at middle positions in a height direction of the mid-plane, the plurality of hard disk connectors are arranged in at least two rows vertically, and the other side of the mid-plane is provided with a controller connector;
a plurality of hard disk assemblies, the hard disk assemblies each comprising the hard disk adapter apparatus as described in any of the foregoing, where the hard disk adapter apparatus is connected to the hard disk connector, and the hard disk assemblies are arranged in one-to-one correspondence with the hard disk connectors; and
a controller, the controller being connected to the controller connector.

In one implementation, the hard disk connectors in two vertically adjacent rows are misaligned.

In one implementation, two adjacent hard disk connectors among the hard disk connectors in any row are equally spaced.

In one implementation, a misalignment size of the hard disk connectors in two vertically adjacent rows is half a distance between the two adjacent hard disk connectors.

In one implementation, the hard disk connectors are partially overlapped in the height direction of the mid-plane.

In one implementation, the hard disk assembly comprises:
a hard disk, provided with a second connecting portion for data connection; and
an adapter board, an adapter portion being connected to the second connecting portion.

In one implementation, the hard disk assembly further comprises a hard disk tray. The hard disk is mounted in the hard disk tray.

In one implementation, two controller connectors are provided, and the two controller connectors are arranged on a top side and a bottom side relative to positions of the hard disk connectors in the mid-plane, respectively.

In one implementation, the two controller connectors are arranged symmetrically about the center of the mid-plane.

In one implementation, one of the two controllers is in reverse plug-in fit with the controller connector on the top side, and the other controller is in forward plug-in fit with the controller connector on the bottom side.

In one implementation, heat dissipation holes penetrating a thickness direction of the mid-plane are provided between the two adjacent hard disk connectors in the mid-plane.

In one implementation, the heat dissipation holes have the same shape and size.

In one implementation, the heat dissipation holes are square holes or oval holes or circular holes or polygonal holes.

According to a third aspect of the present application, a server is provided, comprising the foregoing hard disk storage system.

According to a fourth aspect of the present application, a computer device is provided, comprising the foregoing server.

In the process of using the hard disk adapter apparatus provided by the present application, when the hard disk is connected to the hard disk connector of the mid-plane, the hard disk and the hard disk connector can be connected by the hard disk adapter apparatus. The first connecting portion of the adapter board is centralized in the height direction of the adapter board, thereby facilitating the hard disk connector to be centralized in the height direction of the mid-plane, without interfering the arrangement of the controller connector located on the other side of the mid-plane. In addition, through holes for heat dissipation of the controller can be provided between two adjacent hard disk connectors in the mid-plane, thereby facilitating uniform heat dissipation of the controller.

Furthermore, the present application also provides a hard disk storage system comprising the hard disk adapter apparatus, a server comprising the hard disk storage system, and a computer device comprising the server.

### BRIEF DESCRIPTION OF THE DRAWINGS

In order to describe the embodiments of the present application or the technical solutions in the related art more clearly, drawings required to be used in the embodiments or the illustration of the related art will be briefly introduced below. Apparently, the drawings in the illustration below are only some embodiments of the present application. Those of ordinary skill in the art also can obtain other drawings according to the provided drawings without creative work.

FIG. 1 is a schematic diagram of an appearance structure of a hard disk storage system according to an embodiment of the present application;

FIG. 2 is a schematic diagram of an appearance structure of a hard disk storage system according to an embodiment of the present application from another perspective;

FIG. 3 is a schematic diagram of a structural layout of a hard disk storage system according to an embodiment of the present application;

FIG. 4 is a schematic structural diagram of a hard disk assembly according to an embodiment of the present application;

FIG. 5 is a schematic exploded view of the hard disk assembly of FIG. 4;

FIG. 6 is a schematic diagram of an arrangement mode of a hard disk connector according to an embodiment of the present application;

FIG. 7 is a schematic diagram of connecting a hard disk assembly to a hard disk connector according to an embodiment of the present application;

FIG. 8 is a schematic structural diagram of continuously connecting the hard disk assembly on the basis of FIG. 7;

FIG. 9 is a schematic diagram of an arrangement position of a controller connector according to an embodiment of the present application;

FIG. 10 is a schematic perspective view of a mid-plane according to an embodiment of the present application;

FIG. 11 is a schematic diagram of arrangement positions of a top controller and a bottom controller according to an embodiment of the present application; and

FIG. 12 is a schematic diagram of a connection relationship of a switching chip according to an embodiment of the present application.

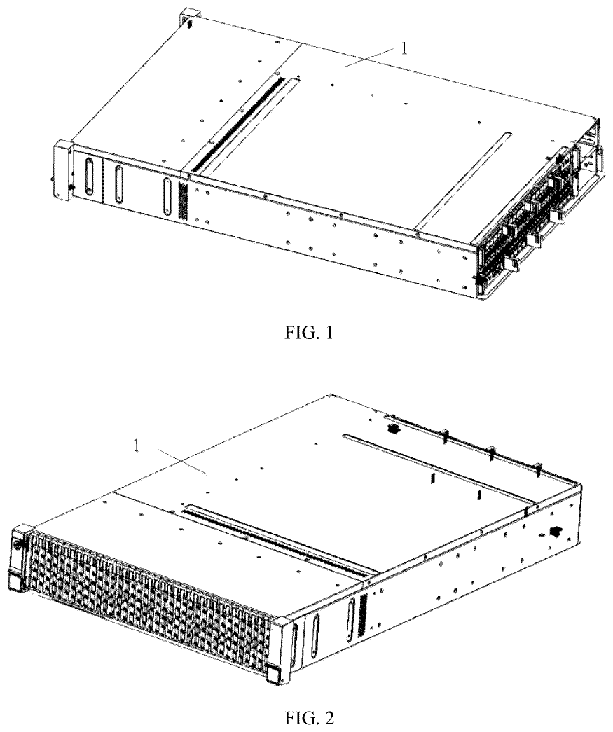

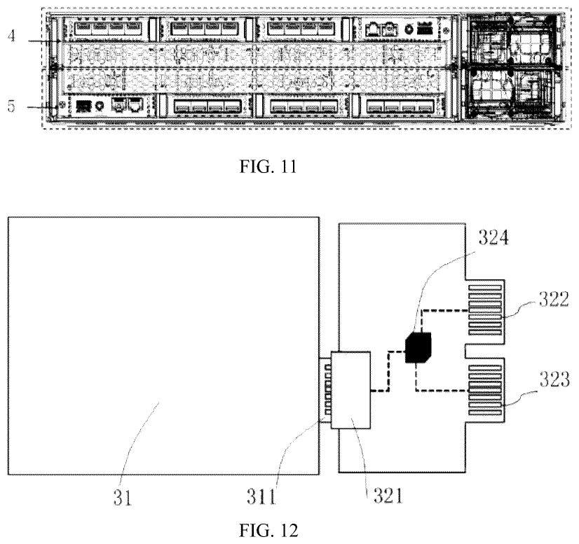

In FIG. 1 to FIG. 12:
1: housing; 2: mid-plane; 21: hard disk connector; 22: controller connector; 3: hard disk assembly; 31: hard disk; 311: second connecting portion; 32: adapter board; 321: adapter portion; 322: first connecting structure; 323: second connecting structure; 324: switching chip; 33: hard disk tray; 4: top controller; 5: bottom controller; 6: heat dissipation hole.

### DETAILED DESCRIPTION

The technical solutions in the embodiments of the present application will be clearly and completely described below with reference to the accompanying drawings in the embodiments of the present application. Obviously, the described embodiments are only a part of the embodiments of the present application, rather than all the embodiments. Based on the embodiments of the present application, all other embodiments obtained by those of ordinary skill in the art without creative work shall fall within the protection scope of the present application.

A core of the present application is to provide a hard disk adapter apparatus. A hard disk and a hard disk connector can be connected by the hard disk adapter apparatus, whereby the hard disk connector can be arranged in the middle of a height direction of a mid-plane, and sufficient space can be reserved for heat dissipation of a controller, thereby facilitating uniform heat dissipation of the controller.

Another core of the present application is to provide a hard disk storage system comprising the hard disk adapter apparatus, a server comprising the hard disk storage system, and a computer device comprising the server.

Reference is made to FIG. 1 to FIG. 12.

This detailed embodiment discloses a hard disk adapter apparatus, including an adapter board 32. One end of the adapter board 32 is provided with an adapter portion 321 connected to a hard disk 31, and the other side of the adapter board 32 is provided with a first connecting portion connected to a hard disk connector 21. The first connecting portion is centralized in a height direction of the adapter board 32.

In the process of using the hard disk adapter apparatus provided by this detailed embodiment, when the hard disk 31 is connected to the hard disk connector 21 of a mid-plane 2, the hard disk 31 and the hard disk connector 21 can be connected by the hard disk adapter apparatus. The first connecting portion of the adapter board 32 is centralized in the height direction of the adapter board 32, thereby facilitating the hard disk connector 21 to be centralized in a height direction of the mid-plane 2, without interfering the arrangement of a controller connector 22 located on the other side of the mid-plane 2. In addition, through holes for heat dissipation of a controller can be provided between two adjacent hard disk connectors 21 in the mid-plane 2, thereby facilitating uniform heat dissipation of the controller.

In addition to the hard disk adapter apparatus, this detailed embodiment also discloses a hard disk storage system, including: a mid-plane 2, where one side of the mid-plane is provided with a plurality of hard disk connectors 21, the plurality of hard disk connectors 21 are arranged at middle positions in a height direction of the mid-plane 2, the plurality of hard disk connectors 21 are arranged in at least two rows vertically, and the other side of the mid-plane 2 is provided with a controller connector 22; a plurality of hard disk assemblies 3, the hard disk assemblies 3 each including the aforementioned hard disk adapter apparatus, where a first connecting portion of the hard disk adapter apparatus is connected to the hard disk connector 21, and the hard disk assemblies 3 are arranged in one-to-one correspondence with the hard disk connectors 21; and a controller, the controller being connected to the controller connector 22.

As shown in FIG. 1 and FIG. 2, a housing 1 is arranged outside the hard disk storage system, and the mid-plane 2 and the hard disk assembly 3 may be arranged in the housing 1.

It should be noted that one side of the mid-plane 2 of the hard disk storage system mentioned in this detailed embodiment is connected to the hard disk assembly 3 through the hard disk connector 21, and the other side of the mid-plane 2 is connected to the controller through the controller connector 22. In the detailed assembly process, when the number of hard disk assemblies 3 is small, only one row of hard disk connectors 21 may be arranged. However, when the number of hard disk assemblies 3 is large, if only one row of hard disk connectors 21 is arranged, the spacing between adjacent hard disk connectors 21 is too small to provide heat dissipation holes 6. Alternatively, even when the number of hard disk connectors 21 in a single row is small, the demand of arranging a larger number of hard disk connectors 21 cannot be met.

In the process of using the hard disk storage system provided by this detailed embodiment, the plurality of hard disk connectors 21 are arranged in at least two rows vertically. When the hard disk assembly 3 has a smaller thickness and a larger quantity, a spacing size between two adjacent hard disk connectors 21 in the mid-plane 2 can be increased as compared with only a single row of hard disk connectors 21, thereby increasing the routing space and improving the rationality of the spatial layout. Moreover, the hard disk connector 21 is centralized in the height direction of the mid-plane 2, without interfering the arrangement of the controller connector 22 located on the other side of the mid-plane 2. In addition, through holes for heat dissipation of a controller can be provided between two adjacent hard disk connectors 21 in the mid-plane 2, thereby facilitating uniform heat dissipation of the controller.

In a detailed embodiment, when the number of arrangement rows of the hard disk connectors 21 is greater than three, the height of the individual hard disk connectors 21 can be reduced due to the limitation of the height of the mid-plane 2, which is determined according to an actual situation and will not be described in detail herein.

The number of arrangement rows of the hard disk connectors 21 may be two, three, or plural, and is determined according to an actual situation.

In this detailed embodiment, the hard disk assemblies 3 and the hard disk connectors 21 are arranged in one-to-one correspondence, whereby a single hard disk assembly 3 can be just connected to one hard disk connector 21, which is convenient for assembly.

When the number of rows of the hard disk connectors 21 is plural, each row of hard disk connectors 21 may be arranged in a length direction of the mid-plane 2. The length direction of the mid-plane 2 is a lateral direction shown in FIG. 6, whereby each row of hard disk connectors 21 occupies the same size in the length direction of the mid-plane 2. Further, the size of the hard disk connector 21 at the end of any row of hard disk connectors 21 from an edge of the mid-plane 2 may be the same or approximately the same, which is determined according to an actual situation and will not be described in detail herein.

It should be noted that the plurality of hard disk connectors 21 mentioned in this detailed embodiment are arranged at middle positions in the height direction of the mid-plane 2. The plurality of rows of hard disk connectors 21 are centralized in the height direction of the mid-plane 2, whereby space for arranging the controller connectors 22 is reserved at a top end and a bottom end in the height direction of the mid-plane 2.

In a detailed arrangement process, there are at least two controller connectors 22 generally. In the process of arranging the hard disk connector 21, if the hard disk connector 21 is located near the top in the height direction of the mid-plane 2, when arranging the controller connectors 22, the bottom controller connector 22 has sufficient arrangement space, but the arrangement space reserved for the top controller connector 22 will be compressed, thereby affecting the normal arrangement of the controller connectors 22. Therefore, it is necessary to centralize the hard disk connector 21 as possible in the height direction of the mid-plane 2.

Preferably, the hard disk connectors 21 located in the same row in this detailed embodiment are located at the same height of the mid-plane 2, whereby the hard disk connectors 21 in the same row are arranged along the same height. At this moment, the individual hard disk connectors 21 have the same height size, and the hard disk connectors 21 in the same row are located at the same height of the mid-plane 2, thereby facilitating the arrangement of the hard disk connectors 21. Also, the top space of the hard disk connectors 21 may be used for arranging the controller connectors 22 to reserve sufficient space.

Further, positions occupied by the hard disk connectors 21 in different rows in the length direction of the mid-plane 2 may be at least partially overlapped, completely overlapped, or only partially overlapped, which may be determined according to an actual situation. When the hard disk connectors 21 in a top row and a bottom row occupy the same size in the length direction of the mid-plane 2, the hard disk connectors 21 in the top row and the bottom row may be completely overlapped in the length direction of the mid-plane 2. At this moment, when the number of hard disk connectors 21 among the hard disk connectors 21 in two vertically adjacent rows is the same and two adjacent hard disk connectors 21 among the hard disk connectors 21 in any row are equally spaced, the hard disk connectors 21 in the top row and the bottom row may be completely overlapped. In other words, the hard disk connectors 21 in the top row and the corresponding hard disk connectors 21 in the bottom row are located at the same position in the length direction of the mid-plane 2. The hard disk connectors 21 in two vertically adjacent rows may be indeed partially overlapped in the length direction of the mid-plane 2. In other words, the positions of the hard disk connectors 21 at the ends of the hard disk connectors 21 in two vertically adjacent rows from the edge of the mid-plane 2 may be different.

In this detailed embodiment, when the hard disk connectors 21 in two vertically adjacent rows are completely overlapped, in the process of connecting the hard disk assembly 3 to the hard disk connector 21, in order to make the hard disk assembly 3 smoothly mounted without interference, a bending structure may be arranged in the hard disk assembly 3, and a portion for connecting to the hard disk connector 21 is connected to the bending structure, whereby one of the two adjacent hard disk connectors 21 is connected to the hard disk connector 21 in the top row, and the other hard disk connector is connected to the opposite hard disk connector 21 in the bottom row. The bending structure may be an L-shaped structure or another structure that meets the requirements, which may be determined according to an actual situation and will not be described in detail herein.

In this detailed embodiment, the positions occupied by the hard disk connectors 21 in different rows in the length direction of the mid-plane 2 are at least partially overlapped, and as many hard disk connectors 21 as possible may be arranged in a case that the length size of the mid-plane 2 is limited. Also, the spacing size between two adjacent hard disk connectors 21 among the hard disk connectors 21 in the same row can be ensured.

In a detailed embodiment, the hard disk connectors 21 in two vertically adjacent rows are misaligned. As shown in FIG. 6, the hard disk connectors 21 in the bottom row are arranged between two adjacent hard disk connectors 21 in the top row, whereby the hard disk connectors 21 in the top row and the bottom row have a certain misalignment size, and the hard disk connectors 21 in two connected rows can make full use of the space in the height direction of the mid-plane 2.

In a detailed arrangement process, in a case that the hard disk connectors 21 in the top row and the corresponding connectors in the bottom row among the hard disk connectors 21 in two adjacent rows are completely aligned, the height size occupied by the hard disk connectors 21 in two adjacent rows in the height direction of the mid-plane 2 is at least the sum of the heights of the two hard disk connectors 21. However, when the hard disk connectors 21 in two adjacent rows are misaligned, the hard disk connectors 21 in the bottom row are located just between two adjacent hard disk connectors 21 in the top row. In the height direction of the mid-plane 2, the hard disk connectors 21 in two adjacent rows may be partially overlapped. In other words, the total height of the hard disk connectors 21 in two adjacent rows in the height direction of the mid-plane 2 may be smaller than the sum of heights of the two hard disk connectors 21. When there are more rows of hard disk connectors 21, the total height size of all the hard disk connectors 21 in the height direction of the mid-plane 2 may be reduced as much as possible.

It should be noted that in this detailed embodiment, the hard disk connectors 21 in two adjacent rows may be only partially overlapped in the height direction of the mid-plane 2, and may not be completely overlapped, so as to reserve space for providing the heat dissipation holes 6 and realize heat dissipation to the controller.

The arrangement height of the hard disk connectors 21 may be the same. In the height direction of the mid-plane 2, the size of the overlapping portion of the hard disk connectors 21 in two vertically adjacent rows may be smaller than half the height of the individual hard disk connectors 21. The size of the overlapping portion of the hard disk connectors 21 in two vertically adjacent rows may be half the height of the individual hard disk connectors 21, or the size of the overlapping portion of the hard disk connectors 21 in two vertically adjacent rows may be slightly larger than half the height of the individual hard disk connectors 21, or another value, which may be determined according to an actual situation and will not be described in detail herein.

In this detailed embodiment, by misaligning the hard disk connectors 21 in two vertically adjacent rows, the height size occupied by the plurality of rows of hard disk connectors 21 in the height direction of the mid-plane 2 can be further reduced, the hard disk connectors 21 in two adjacent rows can be further partially overlapped in the height direction of the mid-plane 2, and the height size occupied by the plurality of rows of hard disk connectors 21 in the height direction of the mid-plane 2 can be further reduced, so as to realize the mounting of a larger number of hard disk connectors 21 in a case that the height of the mid-plane 2 is unchanged. Also, the spacing distance between the two adjacent hard disk connectors 21 is ensured for reserving space for subsequently providing the heat dissipation holes 6.

It should be noted that in this detailed embodiment, the hard disk connectors 21 in two vertically adjacent rows are overlapped in the height direction of the mid-plane 2, and the hard disk connectors 21 in two vertically adjacent rows are misaligned, which will compress the space for providing the heat dissipation holes 6. Therefore, the overlapping size of the hard disk connectors 21 in two vertically adjacent rows in the height direction of the mid-plane 2 needs to be rigorously calculated and is determined according to an actual situation.

In a detailed embodiment, two adjacent hard disk connectors 21 among the hard disk connectors 21 in any row are equally spaced. As shown in FIG. 6, the spacing size between two adjacent hard disk connectors 21 in the top row is equal to the spacing size between two adjacent hard disk connectors 21 in the bottom row.

The heat dissipation holes 6 are mainly provided between the two adjacent hard disk connectors 21, whereby the controller may sufficiently dissipate heat. Therefore, the spacing size between the two adjacent hard disk connectors 21 should not be too small, which may be determined according to an actual situation and will not be described in detail herein.

In this detailed embodiment, two adjacent hard disk connectors 21 among the hard disk connectors 21 in any row are equally spaced, whereby the neat and uniform distribution of the hard disk connectors 21 can be realized, and it can be ensured that two adjacent hard disk connectors 21 are equally spaced, thereby facilitating the provision of the uniformly distributed heat dissipation holes 6, whereby all parts of the controller can uniformly dissipate heat. Also, in the process of mounting the hard disk assembly 3, two adjacent hard disk assemblies 3 may be equally spaced, thereby improving the integrity of the mounting process of the hard disk assembly 3.

In a detailed embodiment, a misalignment size of the hard disk connectors 21 in two vertically adjacent rows is half a distance between the two adjacent hard disk connectors 21. As shown in FIG. 6, the hard disk connectors 21 in the bottom row are located just in the middle position between two adjacent hard disk connectors 21 in the top row. In an actual process of mounting the hard disk assembly 3, it can be ensured that two adjacent hard disk connectors 21 are equally spaced, thereby facilitating the provision of the uniformly distributed heat dissipation holes 6, whereby all parts of the controller can uniformly dissipate heat. Also, in the process of mounting the hard disk assembly 3, two adjacent hard disk assemblies 3 may be equally spaced, thereby improving the integrity of the mounting process of the hard disk assembly 3.

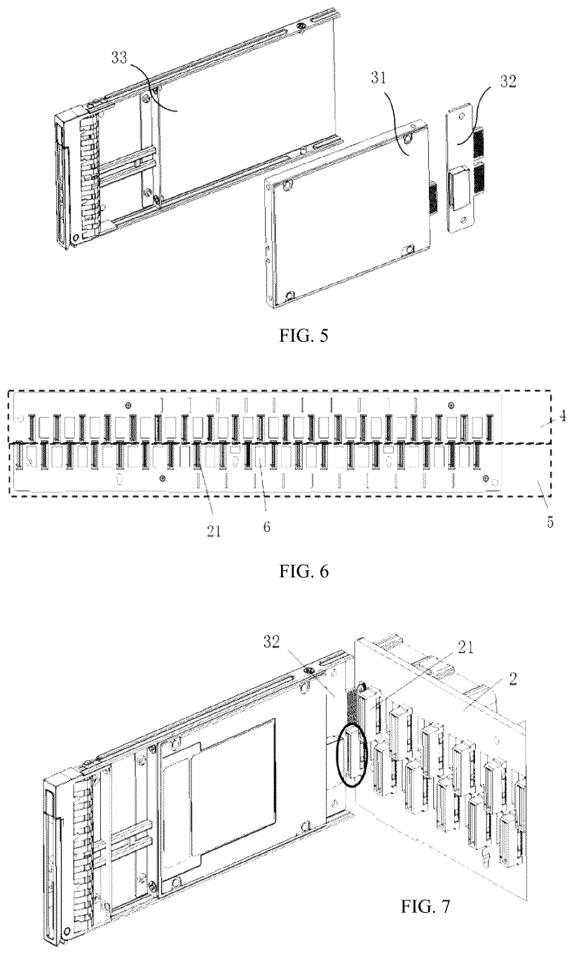

In a detailed embodiment, as shown in FIG. 5, the hard disk assembly 3 includes: a hard disk 31, provided with a second connecting portion 311 for data connection; and an adapter board 32. One end of the adapter board 32 is provided with an adapter portion 321 connected to the second connecting portion 311, and the other side of the adapter board 32 is provided with a first connecting portion connected to a hard disk connector 21. The first connecting portion is centralized in a height direction of the adapter board 32.

During actual use, the second connecting portion 311 of some hard disk 31 is not centralized in a height direction of the hard disk 31. However, when the hard disk 31 is connected to the mid-plane 2, the hard disk connector 21 needs to be located at the middle position in the height direction of the mid-plane 2. Therefore, it is necessary to connect the position of the second connecting portion 311 through the adapter board 32, the adapter portion 321 connected to the second connecting portion 311 is arranged on one side of the adapter board 32, and the first connecting portion connected to the hard disk connector 21 is arranged on the other side of the adapter board 32. The first connecting portion is centralized in the height direction of the adapter board 32, the second connecting portion 311 of the hard disk 31 is connected to the adapter portion 321 of the adapter board 32, and the hard disk 31 and the adapter board 32, taken as an entirety, are connected to the hard disk connector 21 through the first connecting portion. At this moment, the first connecting portion is centralized in the height direction of the hard disk assembly 3, and the hard disk connector 21 is centralized in the height direction of the mid-plane 2, whereby the centralizing of the hard disk assembly 3 can be realized.

It should be noted that the adapter board 32 may have a board-like structure with the same height size as that of the hard disk 31 in the height direction, or may have an irregular structure, which may be determined according to an actual situation and will not be described in detail herein.

Moreover, in the same hard disk assembly 3, only one adapter board 32 may be arranged, or two or more adapter boards 32 may be arranged. For example, two adapter boards 32 may be arranged, where the adapter portion 321 of one adapter board 32 is connected to the second connecting portion 311 of the hard disk 31, the first connecting portion is connected to the adapter portion 321 of the other adapter board 32, and the first connecting portion of the other adapter board 32 is connected to the hard disk connector 21. Another number of adapter boards 32 may be indeed arranged, which may be determined according to an actual situation and will not be described in detail herein.

In a detailed connecting process, when the number of adapter boards 32 in the same hard disk assembly 3 is plural, the corresponding adapter boards 32 may be selected for different types of hard disk connectors 21 according to different types of hard disk connectors 21.

Preferably, the thickness of the adapter board 32 may be smaller than or equal to the thickness of the hard disk 31, thereby preventing the adapter board 32 from additionally occupying space in the thickness direction of the hard disk 31.

Compared with the related art, by arranging the adapter board 32 in this detailed embodiment, it is possible to realize the centralizing when the hard disk 31 is connected to the hard disk connector 21, thereby avoiding the situation that the hard disk assembly 3 is not centralized in the height direction when being connected to the mid-plane 2, and facilitating the hard disk storage system to form a rectangular parallelepiped box-shaped structure with regular shape and size.

In a detailed embodiment, the first connecting portion may include a plurality of connecting structures arranged along the height direction of the adapter board 32. The connecting structures are connected to the hard disk connectors 21. The number of the connecting structures in the individual adapter boards 32 is the same as the number of arrangement rows of the hard disk connectors 21.

In a detailed mounting process, a plurality of rows of hard disk connectors 21 may be arranged, and the number of the connecting structures in the individual adapter boards 32 is the same as the number of arrangement rows of the hard disk connectors 21. When the first hard disk assembly 3 is mounted, the top connecting structure of the adapter board 32 of the hard disk assembly 3 may be connected to the hard disk connector 21 at the end of the hard disk connectors 21 in the top row. When the second hard disk assembly 3 is mounted, the connecting structure adjacent to the top connecting structure in the adapter board 32 of the second hard disk assembly 3 may be connected to the hard disk connector 21 at the end of the hard disk connectors 21 in a second row. The hard disk connectors 21 in the second row refer to the hard disk connectors 21 in the second row adjacent to the hard disk connectors 21 in the top row from top to bottom. By analogy, when the third hard disk assembly 3 is mounted, the third connecting structure in the adapter board 32 of the third hard disk assembly 3 may be connected to the hard disk connector 21 at the end of the hard disk connectors 21 in a third row. The third connecting structure refers to the third connecting structure in the hard disk assembly 3 from top to bottom. The hard disk connectors 21 in the third row refer to the hard disk connectors 21 in the third row adjacent to the hard disk connectors 21 in the second row from top to bottom. When the hard disk connectors 21 at the ends of the hard disk connectors 21 in all rows are all connected to the hard disk assembly 3, the top connecting structure of a next hard disk assembly 3 is connected to a second hard disk connector 21 among the hard disk connectors 21 in the top row. The second hard disk connector 21 refers to a hard disk connector 21 adjacent to the hard disk connector 21 at the end of the hard disk connectors 21 in the top row. All the hard disk assemblies 3 are connected to the hard disk connectors 21 eventually.

Three rows of hard disk connectors 21 may be arranged, and the hard disk connectors 21 in two vertically adjacent rows are misaligned. The first connecting portion includes a first connecting structure 322, a second connecting structure 323, and a third connecting structure spaced apart in the height direction of the adapter board 32. The first connecting structure 322 is connected to the hard disk connector 21 in the top row. The second connecting structure 323 is connected to the hard disk connector 21 in the middle row. The third connecting structure is connected to the hard disk connector 21 in the bottom row. In a detailed assembly process, all the hard disk assemblies 3 are provided with the first connecting structure 322, the second connecting structure 323, and the third connecting structure. Therefore, all the hard disk assemblies 3 have the same structure, thereby effectively avoiding the problem of plugging error. When the first hard disk assembly 3 is mounted, the first connecting structure 322 of the first hard disk assembly 3 may be connected to the hard disk connector 21 at the end of the hard disk connectors 21 in the top row. When the second hard disk assembly 3 is mounted, the second connecting structure 323 of the second hard disk assembly 3 may be connected to the hard disk connector 21 at the end of the hard disk connectors 21 in the middle row. When the third hard disk assembly 3 is mounted, the third connecting structure of the third hard disk assembly 3 may be connected to the hard disk connectors 21 in the bottom row.

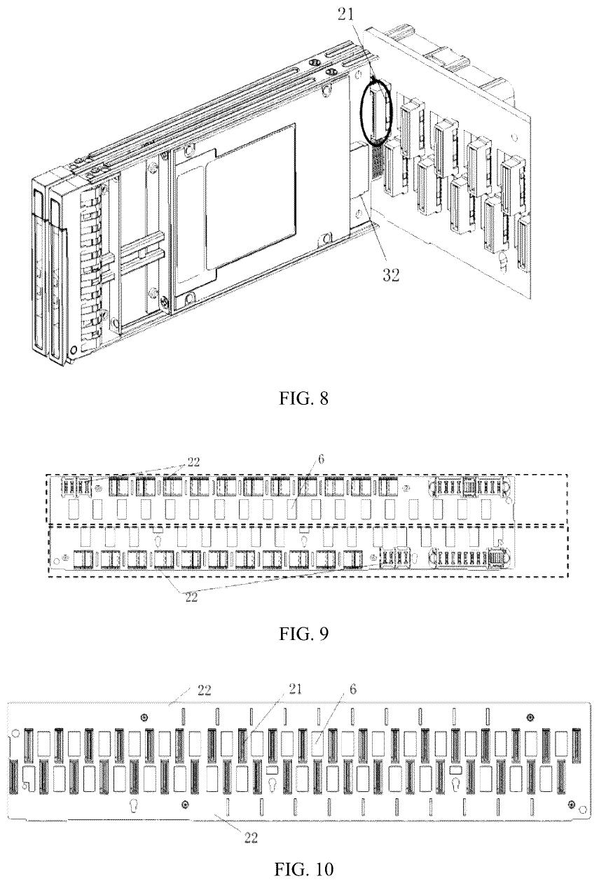

Alternatively, hard disk connectors 21 in a top row and a bottom row may be arranged. The first connecting portion includes a first connecting structure 322 and a second connecting structure 323 spaced apart in the height direction of the adapter board 32. The first connecting structure 322 is connected to the hard disk connector 21 in the top row. The second connecting structure 323 is connected to the hard disk connector 21 in the bottom row. In a detailed assembly process, as shown in FIG. 7 and FIG. 8, all the hard disk assemblies 3 are provided with the first connecting structure 322 and the second connecting structure 323. Therefore, all the hard disk assemblies 3 have the same structure, thereby effectively avoiding the problem of plugging error. When the first hard disk assembly 3 is mounted, the first connecting structure 322 of the first hard disk assembly 3 may be connected to the hard disk connector 21 at the end of the hard disk connectors 21 in the top row. When the second hard disk assembly 3 is mounted, the second connecting structure 323 of the second hard disk assembly 3 may be connected to the hard disk connector 21 at the end of the hard disk connectors 21 in the bottom row.

In this detailed embodiment, the number of connecting structures and the arrangement modes of all the hard disk assemblies 3 are the same, and there is no need to distinguish the hard disk assemblies 3 during the mounting process, whereby errors in the mounting process of the hard disk assemblies 3 can be avoided, and the assembly accuracy rate can be improved.

In a detailed embodiment, the first connecting portion in the adapter board 32 may be not centralized in the height direction of the hard disk assembly 3. For example, two rows of hard disk connectors 21 may be arranged, and the two rows of hard disk connectors 21 are misaligned. The hard disk assembly 3 is divided into two hard disk assemblies, where the first connecting portion of the adapter board 32 in the first hard disk assembly 3 is arranged near the top and is connected to the hard disk connector 21 in the top row, and the first connecting portion of the adapter board 32 in the second hard disk assembly 3 is arranged near the bottom and is connected to the hard disk connector 21 in the bottom row. In an assembly process, different hard disk assemblies 3 need to be distinguished, whereby the first hard disk assembly 3 is connected to the hard disk connector 21 in the top row, and the second hard disk assembly 3 is connected to the hard disk connector 21 in the bottom row.

In this detailed embodiment, the first connecting portion in the adapter board 32 may be not centralized in the height direction of the hard disk assembly 3, and three rows of hard disk connectors 21 may be arranged. The hard disk assembly 3 is divided into three hard disk assemblies, where the first connecting portion of the adapter board 32 in the first hard disk assembly 3 is arranged near the top and is connected to the hard disk connector 21 in the top row, the first connecting portion of the adapter board 32 in the second hard disk assembly 3 is arranged near the bottom and is connected to the hard disk connector 21 in the bottom row, and the first connecting portion of the adapter board 32 in the third hard disk assembly 3 is located in the middle of the hard disk assembly 3 and is connected to the hard disk connector 21 in the middle row. In an assembly process, different hard disk assemblies 3 need to be distinguished, whereby the first hard disk assembly 3 is connected to the hard disk connector 21 in the top row, the second hard disk assembly 3 is connected to the hard disk connector 21 in the bottom row, and the third hard disk assembly 3 is connected to the hard disk connector 21 in the middle row.

Compared with the related art, during the processing of the hard disk assembly 3 in this detailed embodiment, various adapter boards 32 need to be processed, and different hard disk assemblies 3 need to be distinguished in the assembly process. However, after the hard disk assembly 3 is connected to the hard disk connector 21, since the same hard disk assembly 3 is provided with only one first connecting portion and the first connecting portion includes only one connecting structure, it is not necessary to distinguish which detailed connecting structure is connected to the hard disk connector 21, thereby facilitating the control of the connecting portion of the adapter board 32.

In a detailed embodiment, when the first connecting portion of the same adapter board 32 includes at least two connecting structures, the adapter board 32 may be provided with a control member for connecting the adapter portion 321 and the first connecting portion. The control member is configured to connect the adapter portion 321 to one of the connecting structures in the first connecting portion to realize communication between the hard disk connector 21 and the second connecting portion 311.

When the first connecting portion includes a first connecting structure 322 and a second connecting structure 323, the control member may be set as a switching chip 324 embedded in the adapter board 32. The first connecting structure 322 is provided with a first sensing member for detecting whether the first connecting structure is connected to the hard disk connector 21, and the second connecting structure 323 is provided with a second sensing member for detecting whether the second connecting structure is connected to the hard disk connector 21. The first sensing member and the second sensing member are both connected to the switching chip 324. The switching chip 324 controls the adapter portion 321 to be connected to the first connecting structure 322 when receiving a signal that is sent by the first sensing member and indicates that the first connecting structure 322 is connected to the hard disk connector 21. The switching chip 324 controls the adapter portion 321 to be connected to the second connecting structure 323 when receiving a signal that is sent by the second sensing member and indicates that the second connecting structure 323 is connected to the hard disk connector 21.

The first sensing member and the second sensing member may be pressure sensing elements. During use, when the first connecting structure 322 is connected to the hard disk connector 21, the first sensing member senses a pressure signal and transmits the signal to the control member. After receiving the signal, the control member controls the first connecting structure 322 and the adapter portion 321 to be turned on, thereby realizing the electrical connection between the adapter portion 321 and the first connecting structure 322. When the second connecting structure 323 is connected to the hard disk connector 21, the second sensing member senses a pressure signal and transmits the signal to the control member. After receiving the signal, the control member controls the second connecting structure 323 and the adapter portion 321 to be turned on, thereby realizing the electrical connection between the adapter portion 321 and the second connecting structure 323.

The first sensing member and the second sensing member may indeed be contact sensing elements. During use, when the first connecting structure 322 is connected to the hard disk connector 21, the first sensing member senses a contact signal and transmits the signal to the control member. After receiving the signal, the control member controls the first connecting structure 322 and the adapter portion 321 to be turned on, thereby realizing the electrical connection between the adapter portion 321 and the first connecting structure 322. When the second connecting structure 323 is connected to the hard disk connector 21, the second sensing member senses a contact signal and transmits the signal to the control member. After receiving the signal, the control member controls the first connecting structure 322 and the adapter portion 321 to be turned on, thereby realizing the electrical connection between the adapter portion 321 and the second connecting structure 323.

In a detailed setting process, the first sensing member may be set as a pressure sensing member, and the second sensing member may be set as a contact sensing member. During use, when the first connecting structure 322 is connected to the hard disk connector 21, the first sensing member senses a pressure signal and transmits the signal to the control member. After receiving the signal, the control member controls the first connecting structure 322 and the adapter portion 321 to be turned on, thereby realizing the electrical connection between the second connecting portion 311 and the first connecting structure 322. When the second connecting structure 323 is connected to the hard disk connector 21, the second sensing member senses a contact signal and transmits the signal to the control member. After receiving the signal, the control member controls the first connecting structure 322 and the adapter portion 321 to be turned on, thereby realizing the electrical connection between the second connecting portion 311 and the second connecting structure 323.

Alternatively, the first sensing member may be set as a contact sensing member, and the second sensing member may be set as a pressure sensing member. During use, when the first connecting structure 322 is connected to the hard disk connector 21, the first sensing member senses a contact signal and transmits the signal to the control member. After receiving the signal, the control member controls the first connecting structure 322 and the adapter portion 321 to be turned on, thereby realizing the electrical connection between the second connecting portion 311 and the first connecting structure 322. When the second connecting structure 323 is connected to the hard disk connector 21, the second sensing member senses a pressure signal and transmits the signal to the control member. After receiving the signal, the control member controls the second connecting structure 323 and the adapter portion 321 to be turned on, thereby realizing the electrical connection between the second connecting portion 311 and the second connecting structure 323.

Alternatively, the first sensing member and the second sensing member may be both electric sensing members. During use, when the first connecting structure 322 is connected to the hard disk connector 21, the first sensing member senses an electric signal and transmits the signal to the control member. After receiving the signal, the control member controls the first connecting structure 322 and the adapter portion 321 to be turned on, thereby realizing the electrical connection between the second connecting portion 311 and the first connecting structure 322. When the second connecting structure 323 is connected to the hard disk connector 21, the second sensing member senses an electric signal and transmits the signal to the control member. After receiving the signal, the control member controls the second connecting structure 323 and the adapter portion 321 to be turned on, thereby realizing the electrical connection between the second connecting portion 311 and the second connecting structure 323.

The first sensing member and the second sensing member may also be other sensing members that meet the requirements, which may be determined according to an actual situation and will not be described in detail herein.

When the first connecting portion includes a first connecting structure 322, a second connecting structure 323, and a third connecting structure, the control member may be set as a switching chip 324 embedded in the adapter board 32. The first connecting structure 322 is provided with a first sensing member for detecting whether the first connecting structure is connected to the hard disk connector 21, the second connecting structure 323 is provided with a second sensing member for detecting whether the second connecting structure is connected to the hard disk connector 21, and the third connecting structure is provided with a third sensing member for detecting whether the third connecting structure is connected to the hard disk connector 21. The first sensing member, the second sensing member, and the third sensing member are all connected to the switching chip 324. The switching chip 324 controls the adapter portion 321 to be connected to the first connecting structure 322 when receiving a signal that is sent by the first sensing member and indicates that the first connecting structure 322 is connected to the hard disk connector 21. The switching chip 324 controls the adapter portion 321 to be connected to the second connecting structure 323 when receiving a signal that is sent by the second sensing member and indicates that the second connecting structure 323 is connected to the hard disk connector 21. The switching chip 324 controls the adapter portion 321 to be connected to the third connecting structure when receiving a signal that is sent by the third sensing member and indicates that the third connecting structure is connected to the hard disk connector 21.

The first sensing member, the second sensing member, and the third sensing member may be pressure sensing elements. During use, when the first connecting structure 322 is connected to the hard disk connector 21, the first sensing member senses a pressure signal and transmits the signal to the control member. After receiving the signal, the control member controls the first connecting structure 322 and the adapter portion 321 to be turned on, thereby realizing the electrical connection between the second connecting portion 311 and the first connecting structure 322. When the second connecting structure 323 is connected to the hard disk connector 21, the second sensing member senses a pressure signal and transmits the signal to the control member. After receiving the signal, the control member controls the second connecting structure 323 and the adapter portion 321 to be turned on, thereby realizing the electrical connection between the second connecting portion 311 and the second connecting structure 323. When the third connecting structure is connected to the hard disk connector 21, the third sensing member senses a pressure signal and transmits the signal to the control member. After receiving the signal, the control member controls the third connecting structure and the adapter portion 321 to be turned on, thereby realizing the electrical connection between the second connecting portion 311 and the third connecting structure.

The first sensing member, the second sensing member, and the third sensing member may indeed be contact sensing elements. During use, when the first connecting structure 322 is connected to the hard disk connector 21, the first sensing member senses a contact signal and transmits the signal to the control member. After receiving the signal, the control member controls the first connecting structure 322 and the adapter portion 321 to be turned on, thereby realizing the electrical connection between the second connecting portion 311 and the first connecting structure 322. When the second connecting structure 323 is connected to the hard disk connector 21, the second sensing member senses a contact signal and transmits the signal to the control member. After receiving the signal, the control member controls the second connecting structure 323 and the adapter portion 321 to be turned on, thereby realizing the electrical connection between the second connecting portion 311 and the second connecting structure 323. When the third connecting structure is connected to the hard disk connector 21, the third sensing member senses a contact signal and transmits the signal to the control member. After receiving the signal, the control member controls the third connecting structure and the adapter portion 321 to be turned on, thereby realizing the electrical connection between the second connecting portion 311 and the third connecting structure.

Alternatively, the first sensing member and the second sensing member may be pressure sensing elements, and the third sensing member may be a contact sensing element. During use, when the first connecting structure 322 is connected to the hard disk connector 21, the first sensing member senses a pressure signal and transmits the signal to the control member. After receiving the signal, the control member controls the first connecting structure 322 and the adapter portion 321 to be turned on, thereby realizing the electrical connection between the second connecting portion 311 and the first connecting structure 322. When the second connecting structure 323 is connected to the hard disk connector 21, the second sensing member senses a pressure signal and transmits the signal to the control member. After receiving the signal, the control member controls the second connecting structure 323 and the adapter portion 321 to be turned on, thereby realizing the electrical connection between the second connecting portion 311 and the second connecting structure 323. When the third connecting structure is connected to the hard disk connector 21, the third sensing member senses a contact signal and transmits the signal to the control member. After receiving the signal, the control member controls the third connecting structure and the adapter portion 321 to be turned on, thereby realizing the electrical connection between the second connecting portion 311 and the third connecting structure.

Alternatively, the first sensing member may be a contact sensing element, and the second sensing member and the third sensing member may be pressure sensing elements. During use, when the first connecting structure 322 is connected to the hard disk connector 21, the first sensing member senses a contact signal and transmits the signal to the control member. After receiving the signal, the control member controls the first connecting structure 322 and the adapter portion 321 to be turned on, thereby realizing the electrical connection between the second connecting portion 311 and the first connecting structure 322. When the second connecting structure 323 is connected to the hard disk connector 21, the second sensing member senses a pressure signal and transmits the signal to the control member. After receiving the signal, the control member controls the second connecting structure 323 and the adapter portion 321 to be turned on, thereby realizing the electrical connection between the second connecting portion 311 and the second connecting structure 323. When the third connecting structure is connected to the hard disk connector 21, the third sensing member senses a pressure signal and transmits the signal to the control member. After receiving the signal, the control member controls the third connecting structure and the adapter portion 321 to be turned on, thereby realizing the electrical connection between the second connecting portion 311 and the third connecting structure.

Alternatively, the first sensing member and the second sensing member may be contact sensing elements, and the third sensing member may be a pressure sensing element. During use, when the first connecting structure 322 is connected to the hard disk connector 21, the first sensing member senses a contact signal and transmits the signal to the control member. After receiving the signal, the control member controls the first connecting structure 322 and the adapter portion 321 to be turned on, thereby realizing the electrical connection between the second connecting portion 311 and the first connecting structure 322. When the second connecting structure 323 is connected to the hard disk connector 21, the second sensing member senses a contact signal and transmits the signal to the control member. After receiving the signal, the control member controls the second connecting structure 323 and the adapter portion 321 to be turned on, thereby realizing the electrical connection between the second connecting portion 311 and the second connecting structure 323. When the third connecting structure is connected to the hard disk connector 21, the third sensing member senses a pressure signal and transmits the signal to the control member. After receiving the signal, the control member controls the third connecting structure and the adapter portion 321 to be turned on, thereby realizing the electrical connection between the second connecting portion 311 and the third connecting structure.

Alternatively, the first sensing member, the second sensing member, and the third sensing member may all be electric sensing elements. During use, when the first connecting structure 322 is connected to the hard disk connector 21, the first sensing member senses an electric signal and transmits the signal to the control member. After receiving the signal, the control member controls the first connecting structure 322 and the adapter portion 321 to be turned on, thereby realizing the electrical connection between the second connecting portion 311 and the first connecting structure 322. When the second connecting structure 323 is connected to the hard disk connector 21, the second sensing member senses an electric signal and transmits the signal to the control member. After receiving the signal, the control member controls the second connecting structure 323 and the adapter portion 321 to be turned on, thereby realizing the electrical connection between the second connecting portion 311 and the second connecting structure 323. When the third connecting structure is connected to the hard disk connector 21, the third sensing member senses an electric signal and transmits the signal to the control member. After receiving the signal, the control member controls the third connecting structure and the adapter portion 321 to be turned on, thereby realizing the electrical connection between the second connecting portion 311 and the third connecting structure.

Alternatively, the first sensing member may be an electric sensing element, the second sensing member may be a contact sensing element, and the third sensing member may be a pressure sensing element. During use, when the first connecting structure 322 is connected to the hard disk connector 21, the first sensing member senses an electric signal and transmits the signal to the control member. After receiving the signal, the control member controls the first connecting structure 322 and the adapter portion 321 to be turned on, thereby realizing the electrical connection between the second connecting portion 311 and the first connecting structure 322. When the second connecting structure 323 is connected to the hard disk connector 21, the second sensing member senses a contact signal and transmits the signal to the control member. After receiving the signal, the control member controls the second connecting structure 323 and the adapter portion 321 to be turned on, thereby realizing the electrical connection between the second connecting portion 311 and the second connecting structure 323. When the third connecting structure is connected to the hard disk connector 21, the third sensing member senses a pressure signal and transmits the signal to the control member. After receiving the signal, the control member controls the third connecting structure and the adapter portion 321 to be turned on, thereby realizing the electrical connection between the second connecting portion 311 and the third connecting structure.

The first sensing member, the second sensing member, and the third sensing member may also be other sensing structures that meet the requirements, which may be determined according to an actual situation and will not be described in detail herein.

In this detailed embodiment, the adapter boards 32 in all the hard disk assemblies 3 have the same structure, and it is unnecessary to produce different types of adapter boards 32, thereby saving processing time. In addition, in the mounting process, it is unnecessary to consider the difference of different hard disk assemblies 3, thereby effectively avoiding mounting error. Furthermore, after the first connecting portion of the hard disk assembly 3 is connected to the hard disk connector 21, it is possible to automatically identify which detailed connecting structure is connected to the hard disk connector 21, and the control member automatically switches the connection between the connecting structure and the adapter portion 321, whereby the use process is convenient, and the operation is simple.

Preferably, the second connecting portion 311, the first connecting structure 322, and the second connecting structure 323 may all be set as golden fingers. When the second connecting structure 323 includes a plurality of connecting structures, the plurality of connecting structures may all be set as golden fingers. Only some of the connecting structures may indeed be set as golden fingers, which may be determined according to an actual situation and will not be described in detail herein.

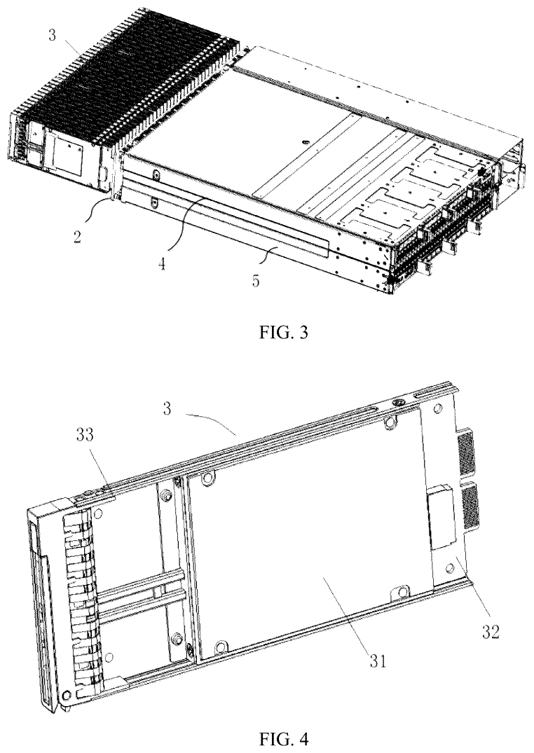

As shown in FIG. 5, the hard disk assembly 3 further includes a hard disk tray 33. The hard disk 31 is mounted in the hard disk tray 33. Both the hard disk 31 and the adapter board 32 may be arranged in the hard disk tray 33, and the hard disk tray 33 may be half-wrapped or fully wrapped around the outer periphery of the hard disk 31 and the adapter board 32 to protect the hard disk 31 and the adapter board 32. As shown in FIG. 4, the shape of the assembled hard disk assembly 3 is relatively regular, which is convenient for transportation and mounting.

The hard disk tray 33 may have a frame-type structure or a housing-type structure, which may be determined according to an actual situation and will not be described in detail herein. The hard disk tray 33 may be made of metal or plastic, which may be determined according to an actual situation and will not be described in detail herein.

In a detailed embodiment, there are two controller connectors 22, and the two controller connectors 22 are arranged on a top side and a bottom side relative to positions of the hard disk connectors 21 in the mid-plane 2, respectively. In a detailed arrangement process, since the hard disk connector 21 is located at the middle position in the height direction on the other side of the mid-plane 2, there is no interference to the arrangement of the controller connector 22. The two controller connectors 22 may be arranged on the top side and the bottom side of the corresponding position of the hard disk connector 21. However, the hard disk connector 21 and the controller connector 22 are located on both sides of the mid-plane 2.

As shown in FIG. 9 to FIG. 11, the two controller connectors 22 are arranged symmetrically about the center of the mid-plane 2. A top controller 4 in the two controllers is in reverse plug-in fit with the controller connector 22 on the top side, and a bottom controller 5 in the two controllers is in forward plug-in fit with the controller connector 22 on the bottom side.

As shown in FIG. 11, the two controller connectors 22 in this detailed embodiment are arranged on the top side and the bottom side of the mid-plane 2. A power supply portion of the top controller 4 is arranged on the right side, and a power supply portion of the bottom controller 5 is arranged on the left side, so as to realize the central symmetrical arrangement of the two controllers and facilitate routing.

In the process of arranging the controller connector 22, since the middle position in the height direction of the mid-plane 2 has been occupied by the hard disk connector 21, it is easy to make the controller connector 22 interfere with the hard disk connector 21 by adopting a traditional placement mode of stacking the two controllers up and down. In this detailed embodiment, the two controller connectors 22 are arranged symmetrically about the center of the mid-plane 2, thereby avoiding the interference between the controller connector 22 and the hard disk connector 21. Also, one of the top controller 4 and the bottom controller 5 is plugged forwardly while the other controller is plugged reversely, whereby connecting lines of the two controllers may be routed from both ends, thereby facilitating layout. Moreover, the heat dissipation holes 6 are provided between two adjacent hard disk connectors 21. As shown in FIG. 10, two rows of hard disk connectors 21 are arranged, the two rows of hard disk connectors 21 are centralized, and the heat dissipation holes 6 are provided between two adjacent hard disk connectors 21 among the two rows of hard disk connectors 21. The heat dissipation holes 6 between the two adjacent hard disk connectors 21 among the hard disk connectors 21 in the top row may be used for heat dissipation of the top controller, and the heat dissipation holes 6 between the two adjacent hard disk connectors 21 among the hard disk connectors 21 in the bottom row may be used for heat dissipation of the bottom controller, whereby the top controller and the bottom controller can realize uniform heat dissipation.

It should be noted that when the number of the controller connectors 22 is another value, the size of the controller connectors 22 in the length direction of the mid-plane 2 can be reduced, whereby two controller connectors 22 may be arranged at the same height of the mid-plane 2. A plurality of controller connectors 22 may indeed be stacked, which may be determined according to an actual situation.

As shown in FIG. 10, heat dissipation holes 6 penetrating a thickness direction of the mid-plane 2 are provided between the two adjacent hard disk connectors 21 in the mid-plane 2. The heat dissipation holes 6 are mainly used for heat dissipation of the controller. In this detailed embodiment, since the hard disk connector 21 is arranged at the middle position in the height direction of the mid-plane 2, the heat dissipation holes 6 are also provided at the middle position in the height direction of the mid-plane 2, whereby the top and bottom controllers may uniformly dissipate heat.

The heat dissipation holes 6 may have the same shape and size, and the heat dissipation holes 6 may be square holes or oval holes or circular holes or polygonal holes or in other shapes that meet the requirements, which may be determined according to an actual situation and will not be described in detail herein.

In addition to the hard disk storage system, the present application also provides a server including the hard disk storage system disclosed in the above embodiments. The structure of other parts of the server may be referred to the related art, and will not be described in detail herein.

In a detailed embodiment, the server includes a box structure and the hard disk storage system arranged in the box structure. The hard disk storage system may be detachably arranged in the box structure, and other connection modes may be used between the hard disk storage system and the box structure, which may be determined according to an actual situation and will not be described in detail herein.

In addition to the server, the present application also provides a computer device including the server disclosed in the above embodiments. The structure of other parts of the computer device may be referred to the related art, and will not be described in detail herein.

In a detailed embodiment, the computer device includes a display, an external input device, and the server. The server may have a separate structure, or the server and the display may be configured as an integrated structure, which may be determined according to an actual situation and will not be described in detail herein.

The “first” and “second” in the second connecting portion 311 and the first connecting portion, the first connecting structure 322 and the second connecting structure 323 mentioned in the present application are only for distinguishing positions instead of sequence.

Various embodiments are described in this specification in a progressive manner. Each embodiment focuses on differences from the other embodiments. The same or similar parts of the various embodiments may be referred to each other. Any combination of all embodiments provided by the present application is within the protection scope of the present application, and will not be described in detail herein.

The hard disk adapter apparatus, the hard disk storage system, the server, and the computer device provided by the present application have been described in detail above. The principles and implementations of the present application have been set forth herein using detailed examples. The above embodiments have been set forth only to aid in the understanding of the method and core ideas of the present application. It should be noted that those of ordinary skill in the art may make numerous improvements and modifications to the present application without departing from the principles of the present application. Such improvements and modifications are intended to be within the scope of protection of the appended claims of the present application.

1. A hard disk adapter apparatus, comprising an adapter board, wherein one end of the adapter board is provided with an adapter portion connected to a hard disk, and the other side of the adapter board is provided with a first connecting portion connected to a hard disk connector the first connecting portion being centralized in a height direction of the adapter board.

2. The hard disk adapter apparatus according to claim 1, wherein the first connecting portion comprises a plurality of connecting structures arranged along the height direction of the adapter board, wherein the connecting structures are connected to the hard disk connectors, and the number of the connecting structures in the individual adapter boards is the same as the number of arrangement rows of the hard disk connectors.

3. The hard disk adapter apparatus according to claim 2, wherein the plurality of hard disk connectors are arranged in a top row and a bottom row, and the first connecting portion comprises a first connecting structure and a second connecting structure spaced apart in the height direction of the adapter board, wherein the first connecting structure is connected to the hard disk connector in the top row, and the second connecting structure is connected to the hard disk connector in the bottom row.

4. The hard disk adapter apparatus according to claim 3, wherein the adapter board is provided with a control member connecting the adapter portion and the first connecting portion, wherein the control member is configured to connect the adapter portion to one of the first connecting structure and the second connecting structure, which is connected to the hard disk connector.

5. The hard disk adapter apparatus according to claim 4, wherein the control member is a switching chip embedded in the adapter board.

6. The hard disk adapter apparatus according to claim 5, wherein the first connecting structure is provided with a first sensing member for detecting whether the first connecting structure is connected to the hard disk connector, and the second connecting structure is provided with a second sensing member for detecting whether the second connecting structure is connected to the hard disk connector, wherein the first sensing member and the second sensing member are both connected to the switching chip; and
the switching chip controls the adapter portion to be connected to the first connecting structure in case of receiving a signal that is sent by the first sensing member and indicates that the first connecting structure is connected to the hard disk connector, and the switching chip controls the adapter portion to be connected to the second connecting structure in case of receiving a signal that is sent by the second sensing member and indicates that the second connecting structure is connected to the hard disk connector.

7. The hard disk adapter apparatus according to claim 3, wherein the adapter portion, the first connecting structure, and the second connecting structure are all golden fingers.

8. The hard disk adapter apparatus according to claim 2, wherein the plurality of hard disk connectors are arranged in three rows, and the first connecting portion comprises a first connecting structure, a second connecting structure, and a third connecting structure spaced apart in the height direction of the adapter board, wherein the first connecting structure is connected to the hard disk connector in the top row, the second connecting structure is connected to the hard disk connector in the middle row, and the third connecting structure is connected to the hard disk connector in the bottom row;
the adapter board is provided with a control member connecting the adapter portion and the first connecting portion, wherein the control member is configured to connect the adapter portion to one of the first connecting structure, the second connecting structure, and the third connecting structure, which is connected to the hard disk connector;
the control member is a switching chip embedded in the adapter board;
the first connecting structure is provided with a first sensing member for detecting whether the first connecting structure is connected to the hard disk connector, the second connecting structure is provided with a second sensing member for detecting whether the second connecting structure is connected to the hard disk connector, and the third connecting structure is provided with a third sensing member for detecting whether the third connecting structure is connected to the hard disk connector, wherein the first sensing member, the second sensing member, and the third sensing member are all connected to the switching chip; and
the switching chip controls the adapter portion to be connected to the first connecting structure in case of receiving a signal that is sent by the first sensing member and indicates that the first connecting structure is connected to the hard disk connector, the switching chip controls the adapter portion to be connected to the second connecting structure in case of receiving a signal that is sent by the second sensing member and indicates that the second connecting structure is connected to the hard disk connector, and the switching chip controls the adapter portion to be connected to the third connecting structure in case of receiving a signal that is sent by the third sensing member and indicates that the third connecting structure is connected to the hard disk connector.

9. A hard disk storage system, comprising:
a mid-plane, wherein one side of the mid-plane is provided with a plurality of hard disk connectors, the plurality of hard disk connectors are arranged at middle positions in a height direction of the mid-plane, the plurality of hard disk connectors are arranged in at least two rows vertically, and the other side of the mid-plane is provided with a controller connector;
a plurality of hard disk assemblies, the hard disk assemblies each comprising a hard disk adapter apparatus comprising an adapter board, wherein one end of the adapter board is provided with an adapter portion connected to a hard disk, and the other side of the adapter board is provided with a first connecting portion connected to a hard disk connector, the first connecting portion being centralized in a height direction of the adapter board, wherein the hard disk adapter apparatus is connected to the hard disk connector, and the hard disk assemblies are arranged in one-to-one correspondence with the hard disk connectors; and
a controller, the controller being connected to the controller connector.

10. The hard disk storage system according to claim 9, wherein the hard disk connectors in two vertically adjacent rows are misaligned.

11. The hard disk storage system according to claim 10, wherein two adjacent hard disk connectors among the hard disk connectors in any row are equally spaced.

12. The hard disk storage system according to claim 11, wherein a misalignment size of the hard disk connectors in two vertically adjacent rows is half a distance between the two adjacent hard disk connectors.

13. The hard disk storage system according to claim 9, wherein the hard disk connectors in two adjacent rows are partially overlapped in the height direction of the mid-plane.

14. The hard disk storage system according to claim 9, wherein the hard disk connectors in the same row are located at the same height of the mid-plane.

15. The hard disk storage system according to claim 9, wherein the positions of the hard disk connectors in different rows in a length direction of the mid-plane are partially overlapped.

16. The hard disk storage system according to claim 9, wherein the hard disk assembly comprises:
a hard disk, provided with a second connecting portion for data connection; and
the adapter board, the adapter portion being connected to the second connecting portion.

17. The hard disk storage system according to claim 16, wherein the hard disk assembly further comprises a hard disk tray, wherein the hard disk is mounted in the hard disk tray.

18. The hard disk storage system according to claim 9, wherein two controller connectors are provided, and the two controller connectors are arranged on a top side and a bottom side relative to positions of the hard disk connectors in the mid-plane, respectively.

19. The hard disk storage system according to claim 18, wherein the two controller connectors are arranged symmetrically about the center of the mid-plane.

20-23. (canceled)

24. A server, comprising a hard disk storage system, wherein the hard disk storage system comprises:
a mid-plane, wherein one side of the mid-plane is provided with a plurality of hard disk connectors, the plurality of hard disk connectors are arranged at middle positions in a height direction of the mid-plane, the plurality of hard disk connectors are arranged in at least two rows vertically, and the other side of the mid-plane is provided with a controller connector;
a plurality of hard disk assemblies, the hard disk assemblies each comprising a hard disk adapter apparatus-comprising an adapter board, wherein one end of the adapter board is provided with an adapter portion connected to a hard disk, and the other side of the adapter board is provided with a first connecting portion connected to a hard disk connector, the first connecting portion being centralized in a height direction of the adapter board, wherein the hard disk adapter apparatus is connected to the hard disk connector, and the hard disk assemblies are arranged in one-to-one correspondence with the hard disk connectors; and
a controller, the controller being connected to the controller connector.

25. (canceled)
